(19) United States
(12) Patent Application Publication
(10) Pub. No.: US 2008/0165565 A1
(43) Pub. Date: Jul. 10, 2008

(54) Ferroelectric Thin Films and Devices Comprising Thin Ferroelectric Films

(75) Inventors: Peter Gunter, Riedt-Neerach (CH); Payam Rabiei, Zurich (CH)

Correspondence Address: RANKIN, HILL & CLARK LLP, 38210 Glenn Avenue, WILLOUGHBY, OH, 44094-7808, US

(73) Assignee: EIDGENOSSISCHE TECHNISCHE HOCHSCHULE ZURICH, Zurich (CH)

(21) Appl. No.: 10/597,052

(22) PCT Filed: Jun. 17, 2004
(86) PCT No.: PCT/CH2004/000365

§ 371 Date: Aug. 17, 2006

(30) Foreign Application Priority Data
Jan. 12, 2004 (EP) 04000408.7

(51) Int. Cl. G11C 11/22; B29C 65/00; H01L 41/00; G02B 6/10; B29D 11/00

(52) U.S. Cl. 365/145; 156/273.3; 216/24; 257/295; 310/311; 385/142; 257/E43.005

(57) ABSTRACT

A method of producing a device with a ferroelectric crystal thin film on a first substrate including the steps of providing a ferroelectric crystal, of irradiating a first surface of the ferroelectric crystal with ions so that a damaged layer is created underneath the first surface, of bonding a block of material including the first substrate to the ferroelectric crystal to create a bonded element, wherein an interface is formed between the first surface and a second surface of the block, and of heating the bonded element and separating it at the damaged layer, so that a ferroelectric crystal layer remains supported by the first substrate. By this method, very thin films—down to thicknesses of a fraction of a micrometer—of ferroelectric crystals may be fabricated without jeopardizing the monocrystalline structure.

### BACKGROUND OF THE INVENTION

1. Field of the Invention

The invention generally relates to applications of thin films of ferroelectric materials in integrated optical devices for telecommunication and data communication. The thin films of ferroelectric materials can also be used in applications such as electronic memory devices, pyroelectric detectors and piezoelectric actuators. In particular, the invention relates to fabrication of thin films of nonlinear optical materials, and to integrated optical devices for amplification and switching of light-wave signals.

2. Description of Related Art

Owing to large frequency-bandwidth of optical fibers, light-wave technology provides the ability to send a large amount of data using a very small fiber. To maximize the transmission capability of optical fibers, one has to use wavelength division multiplexing (WDM) technology. The current long-haul communication systems use WDM technology for transmitting large amounts of data over optical fibers.

To build an optical communication system using WDM technology, one is required to generate, amplify, modulate, filter and detect optical signals with different wavelengths. To generate optical signals one needs to be able to amplify the optical signals. To modulate the optical signal, one is required to change the refractive index of the material and use some optical circuit to modulate optical signals. To filter the WDM signals one needs to use optical filters and finally one needs detectors for this purpose.

Generally, these functions are performed with different technologies in optical communication systems. For example, for generation, semiconductor devices are used, for amplification erbium doped fiber amplifiers (EDFA) are used. For modulation, LiNbO₃ Mach-Zehnder modulators are used. To filter the signals, Glass planar waveguide circuits are used. Finally, for detection, different semiconductors are used.

Since different technologies and materials are used, the WDM optical communication systems are usually very expensive and require a large space.

For waveguide circuits and for integrated optical devices, owing to large nonlinear coefficient, ferroelectric crystals such as LiNbO₃ and LiTaO₃ and KNbO₃ are desirable to fabricate thin films with high quality. For the fabrication of thin films several methods have been used in the past. Molecular beam epitaxy, plasma sputtering, laser pulse deposition and some other methods have been used in the past. However the thin films obtained by these methods have two main problems. First, the films can be grown on special substrates, which provide lattice matching to the crystal. This will limit the fabrication process to very few cases and one cannot achieve optical waveguides with desirable properties. Second, the quality of the fabricated films is not as good as bulk crystals. The optical losses are very high and the electro-optic coefficient is very small. A good method for the fabrication of thin films of ferroelectric crystals with high quality does not exist.

The current devices based on the ferroelectric crystals use bulk crystals and they form a low index contrast waveguide in the crystal by ion exchange or diffusion to form optical waveguides. Switching of the light is achieved in these devices by changing the refractive index of the material by applying an electric field to the waveguide. Also, optical amplification is achieved by use of three wave mixing in these crystals. To achieve phase matching, periodic poling is used. The devices for switching and modulation are very big (up to 2 cm long) and the devices for amplification are very long and have small bandwidth.

### BRIEF SUMMARY OF THE INVENTION

It is the general object of this invention to fabricate thin films of nonlinear optical crystals for the fabrication of nonlinear optical devices to be used for generation, modulation, amplification and filtering of light-wave signals.

It is another object of the present invention to introduce new devices, which can be made using the thin films of optical nonlinear materials for amplification, modulation, and filtering of lightwave signals.

It is a still further objective of the present invention to provide new optical communication systems that can be made using the proposed technology.

It is yet another objective of the invention to provide piezoelectric or pyroelectric devices comprising thin films of ferroelectric materials.

A method of producing a device with a ferroelectric crystal thin film on a first substrate comprises the steps of providing a ferroelectric crystal, of irradiating a first surface of the ferroelectric crystal with ions so that a damaged layer is created underneath the first surface, of bonding a block of material including the first substrate to the ferroelectric crystal to create a bonded element, wherein an interface is formed between the first surface and a second surface of the block, and of heating the bonded element and separating it at the damaged layer, so that a ferroelectric crystal layer remains supported by the first substrate. By this method, very thin films, down to thicknesses a fraction of a micrometer, of ferroelectric crystals may be fabricated without jeopardizing the monocrystalline structure.

According to a preferred embodiment, prior to bonding the block to the second substrate, the first substrate is provided with a electrode layer prior to the bonding. This solves the additional problem of finding ways to apply voltages to such a thin ferroelectric crystal layer. In addition to the electrode layer, which may or may not be structured, a top electrode may be placed, so that the ferroelectric layer, including possible cladding layers, is sandwiched between two electrodes. This opens the possibility of specifically using electro-optic, piezoelectric, pyroelectric etc. effects of the ferroelectric material. Specifically, by influencing the index of refraction of a small waveguide, one can achieve switching functionalities.

In this way, a technology is introduced, which can provide all the functions required for integrated optoelectronic devices, including amplification, in a single material. Also using this technology, it is possible to reduce the size of optical devices by factors of 100 to 1000. Since the size is reduced and all the required functions are made in a single material system the price of integrated systems can be reduced significantly.

Another preferred embodiment of the invention is a parametric amplifier comprising a waveguide with a core comprising at least two layers of differently, preferably opposed, poled ferroelectric material. If the interface between such layers is placed at a node of a higher order waveguide mode, the overlap integral between the basic mode and the higher order mode may become large. This is a prerequisite of parametric amplification or frequency doubling being possible with a high efficiency.

A further advantage of the method according to the invention is that the index of refraction of ferroelectric materials is comparably high. For this reason, a high index contrast between a waveguide core and a cladding may be achieved, which allows both waveguide bending with small radius and high energy densities beneficial for optically nonlinear effects.

Since the WDM communication system can be made in a very compact way, it is also possible to use the system for data communication. The speed of computers are now limited by the speed of the communication of signals between different modules in a computer. Using the described technology it is possible to use light-wave signals inside a computer to transmit the data much faster than printed circuit boards currently used.

The wavelengths for which waveguides according to this invention are preferably designed, are the wavelengths preferred by the WDM technology, mainly frequency windows around 850 nm, 1300 nm, and 1550 nm. (for example ±50 nm around each of these center frequencies). However, the invention is by no means restricted to these frequency windows.

The technology introduced is based on the fabrication of thin films of optical materials with large nonlinear coefficients, i.e. ferroelectric thin films. The fabricated ferroelectric thin films can also be used for memory devices, pyroelectric devices and piezoelectric actuators.

In fact, it is one of the important achievements of this invention that electrodes adjacent to both sides of a very thin ferroelectric layer become readily feasible.

### BRIEF DESCRIPTION OF THE DRAWINGS

The above mentioned and I further objects, features and advantages will become apparent upon consideration of the following detailed description of specific embodiments thereof. The description refers to drawings, in which the figures show:

FIG. 1: The fabrication process for preparation of thin films of LiNbO₃ on SiO₂ cladding layers;

FIG. 2: An image for the fabricated LiNbO₃ waveguide;

FIG. 3a: The cross section of a channel waveguide;

FIG. 3b: The cross sections of a ridge waveguide;

FIG. 4: The cross section along the propagation direction for a periodically poled ferroelectric waveguide (upper panel; the arrows indicate the direction of domains), and the electrode structure for periodically polling the ferroelectric waveguide (lower panel);

FIGS. 5a and 5b: Multi-layer waveguides that can be fabricated by repeating the fabrication process invented with crystals with different spontaneous polarization direction vectors;

FIG. 6: A multi-layer LiNbO₃ waveguide with modulated nonlinear susceptibility direction;

FIG. 7: Chromatic dispersion calculated for bulk crystal of LiNbO₃ and the calculated chromatic dispersion for different waveguide configuration. The chromatic dispersion can be forced to zero at the 1.55 mm wavelength by a careful choice of the refractive index of the cladding of the waveguide;

FIG. 8: Calculated gain spectrum for parametric amplification for different cladding index for TM₀^{ω} [symbol] TM₂^{2ω} conversion for different refractive index of cladding for a LiNbO₃ waveguide;

FIG. 9: A Mach-Zehnder modulator structure;

FIG. 10: A micro-ring modulator (switch) structure with coupling waveguides;

FIG. 11: The modulation (switching) of light by shifting the resonance wavelength in an electro-optic micro-resonator;

FIG. 12: A Mach-Zehnder modulator with electro-optic micro-ring resonators coupled to different arms;

FIG. 13: The transmission of the micro-ring coupled Mach-Zehnder structure for different values of the phase difference induced by shifting the resonance wavelengths of the micro-resonators;

FIG. 14: A multi-wavelength modulator (Switch), which uses several micro-resonators with different resonance wavelength;

FIG. 15: A wavelength router, which can route any input wavelength in any input port to any output port;

FIG. 16: A high order filter realized by coupling micro-resonators with different coupling coefficients to different arms of a Mach-Zehnder switch;

FIG. 17: A multi-wavelength switch comprising high order filters for each wavelength;

FIG. 18: An electrode structure for coupling the light of the micro-ring structure for inducing losses in the micro-resonator structure;

FIG. 19: The calculated losses for periodic modulation of refractive index in a micro-resonator as a function of number of periods of electrodes;

FIG. 20: A pyroelectric sensor; and

FIG. 21: A four-bit memory element.

### DETAILED DESCRIPTION OF THE PREFERRED EMBODIMENTS

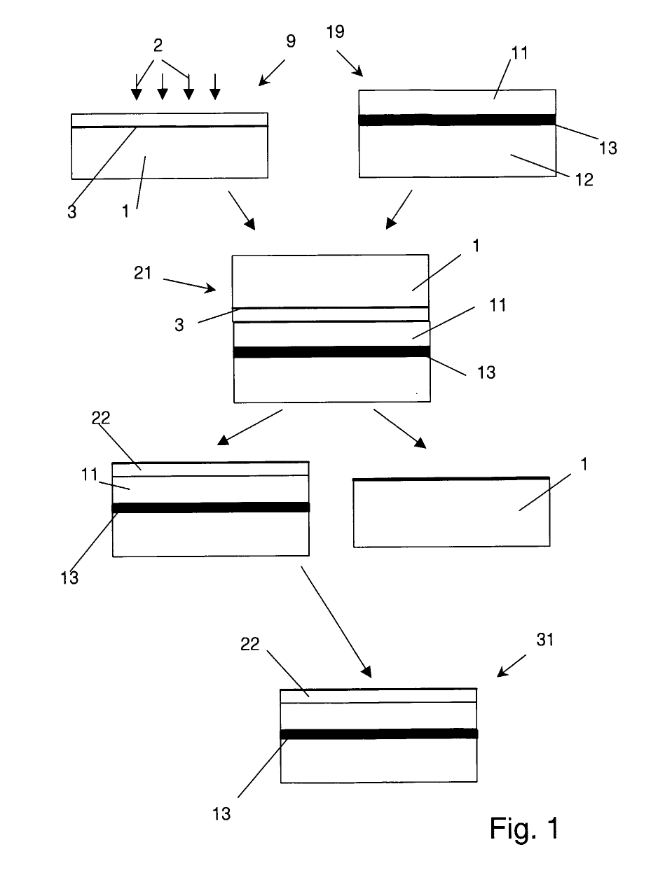

A first general embodiment of the present invention is shown in FIG. 1. This figure shows a basic procedure, which is used for the fabrication of thin films of nonlinear optical crystals. As is shown in FIG. 1, first a LiNbO₃ ferroelectric crystal 1 is ion implanted using ionized He+ ions 2. The He+ ions are accelerated in an electric field and are used to bombard the ferroelectric crystal. The energy for these ions varies between 50 keV to 1 Mev. Because the He+ ions penetrate into the crystal, a damaged layer 3 is formed inside the crystal. In this layer the bonding between the adjacent atoms is broken due to the presence of the He atom.

The ferroelectric crystal in this embodiment as well as in other preferred embodiments is a bulk crystal (as opposed to grown layer films). Bulk crystals in this context are crystals that do not rely on a support (or growth) substrate and the size of which usually exceeds 100 μm in all three dimensions. Bulk crystals may be fabricated from the melt using a seed and are usually cheaper and in much better quality than grown films.

As an alternative to He+ ions, Hydrogen ions or other ions my be used. The nature and the energy of the ions determines the final thickness for the thin film fabricated using this method. The thickness may be tailored between 0.1 μm and 2.5 μm and is usually chosen to be in the range between 0.25 μm and 1 μm for integrated optic applications.

A layer of SiO₂ 11 is deposited on another LiNbO₃ substrate 12, for example using plasma an enhanced chemical vapor deposition system. This layer 11 will behave as a buffer layer or a cladding for an optical waveguide to be fabricated. The thickness of this layer can be between a few nanometers (for example 5 nm) up to 2-5 micrometers. The thickness of this layer may be optimized according to the thickness of the core layer (i.e. the ferroelectric crystal layer to be fabricated) to minimize the coupling of the light to the LiNbO₃ substrate for integrated optic applications. A thin film polishing (CMP polishing) technique may be applied to smooth the surface of the deposited SiO₂ layer.

This other substrate, also called ‘first substrate’ in this application, may as an alternative to being a ferroelectric crystal be made of any substrate material, for example a semiconductor such as Si, a metal etc. It may, depending on the application, also be a glass. ‘Conventional’ substrates such as Si or Glass feature the advantage that they are comparably low in cost, whereas a substrate of the ferroelectric material of the layer has the same coefficient of thermal expansion, so that stress upon the crystal layer during heating steps can be ruled out. The first substrate can also carry an integrated electronic circuit, which might be used to apply the appropriate voltage to the fabricated photonic system made by the said fabrication method.

As an option, previously to being provided with the buffer layer 11, the first substrate 12 may be provided with an electrode layer 13. The electrode layer is an electrically conducting layer, for example of a metal such as copper or any other pure metal or metal alloy or doped semiconductor layer such as doped silicon. It has a thickness enabling it to conduct electricity, for example a thickness of 100 nm.

As an alternative to the above procedure, the electrode layer and/or the buffer layer could in principle also be provided on the crystal which then is bonded to the first substrate. To this end, the buffer layer is added to the crystal surface, and then optionally the electrode is provided on top of the buffer layer. The block of material comprising the first substrate is then bonded to the electrode layer or the buffer layer, respectively. However, by providing the electrode layer and the buffer layer on the first substrate as shown referring to FIG. 1, one can avoid having to grow these layers on the nonlinear crystal material later to become the core layer. This is advantageous since said crystal material is often delicate.

The resulting ion implanted sample 9 and the sample with cladding layer 19 are bonded together, using standard wafer bonding techniques. To achieve this, the samples are cleaned using the organic solvents and using an RCA1 solution that activates their surface. The samples are brought into contact inside de-ionized water and are pressed against each other to form a bond between them. The samples will attach to each other after this process. Next, the resulting bonded element 21 is heat treated to increase the bonding strength and to split and transfer a thin layer of the crystal. It is placed in an oven at temperatures between 100° C. and 600° C. for at least half an hour, for example at 250° C. for 20 hours. A thin layer of crystal 22, to be the core layer, is thereby transferred to the other substrate 12. Hence, one will obtain a thin layer of the ferroelectric crystal 22 using this method. A final product 31 can be further improved by a further annealing and final polishing. Starting from such a final product the ferroelectric crystal may be structured to serve as a waveguide core of a laterally confined (“3d”-) waveguide or an otherwise structured element.

The buffer layer may, for some embodiments, be omitted. For example, the ferroelectric layer may be bonded directly to the electrode.

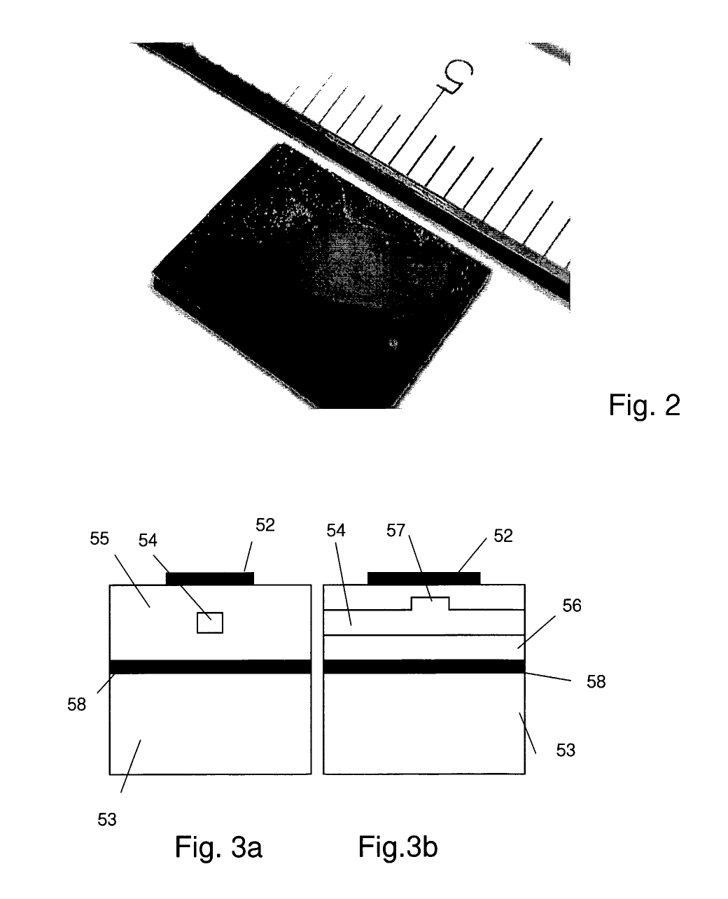

FIG. 2 shows a picture of a thin LiNbO₃ crystal film, which has been made using the described technique. The film is essentially homogeneous and monocrystalline. Since the thin film is directly fabricated from a bulk ferroelectric crystal, it has the optical properties of a bulk crystal. Hence, the optical losses are very small and the measured electro-optic coefficient is very high.

Next, devices comprising thin ferroelectric crystal layers are described. In all embodiments, the ferroelectric crystal layers are fabricated using the above method (the electrode being only present in some embodiments, as described). In all embodiments, the ferroelectric crystal layers may be of LiNbO₃, of LiTaO₃, of KNbO₃, or of any other suitable optically ferroelectric crystal material available or yet to be discovered. In all embodiments that follow, the vertical confinement of the light is achieved by total internal reflection from the upper and lower cladding in the core of the waveguide fabricated. In all embodiments, a lateral confinement of light is achieved by selectively pattering the thin film fabricated using optical or electron beam lithography and plasma etching. The lateral confinement might be strong as shown in FIG. 3a or weak as shown in FIG. 3b. For a weak confinement, only a small part of the core is removed by plasma etching of the ferroelectric crystal. For strong confinement the whole core layer, except at the position of the waveguide, is removed by plasma etching. In the structure of FIG. 3a, the ferroelectric material 54 is laterally confined and is surrounded by cladding material 55, whereas in the structure of FIG. 3b it is provided as a layer that is laterally not confined. In the structure of FIG. 3b, lateral guiding of the lightwaves is accomplished by a thickness of the ferroelectric layer 54 that does not allow plane waves to develop and by a ridge 57 of a material with an index of refraction equal or similar to the one of the ferroelectric layer. In both Figures, both, the lower electrode 58 fabricated by the method described above and the laterally structured top electrode 52 are shown.

The top electrode 52 shown in FIG. 3 may be fabricated at the device surface using any known technique for selectively depositing a metal including techniques involving masks, photolithography and etching techniques etc.

First optical amplification is considered. To achieve an optical amplifier in a nonlinear optical crystal, one has to convert a photon from a strong optical pump signal through nonlinear interaction into two photons, one in the signal wavelength and one in the idler wavelength. The optical signal frequency of the pump and the signal and idler obey the following energy conservation equation:

ωₚ=ωᵢ+ωₛ (1)

To achieve a practical amplifier one needs the phase matching condition to be fulfilled. The phase matching is given by:

n(ωₚ)ωₚ=n(ωₛ)ωₛ+n(ωᵢ)ωᵢ (2)

Therefore, the effective index of different guided modes in a ferroelectric crystal waveguide has to be matched.

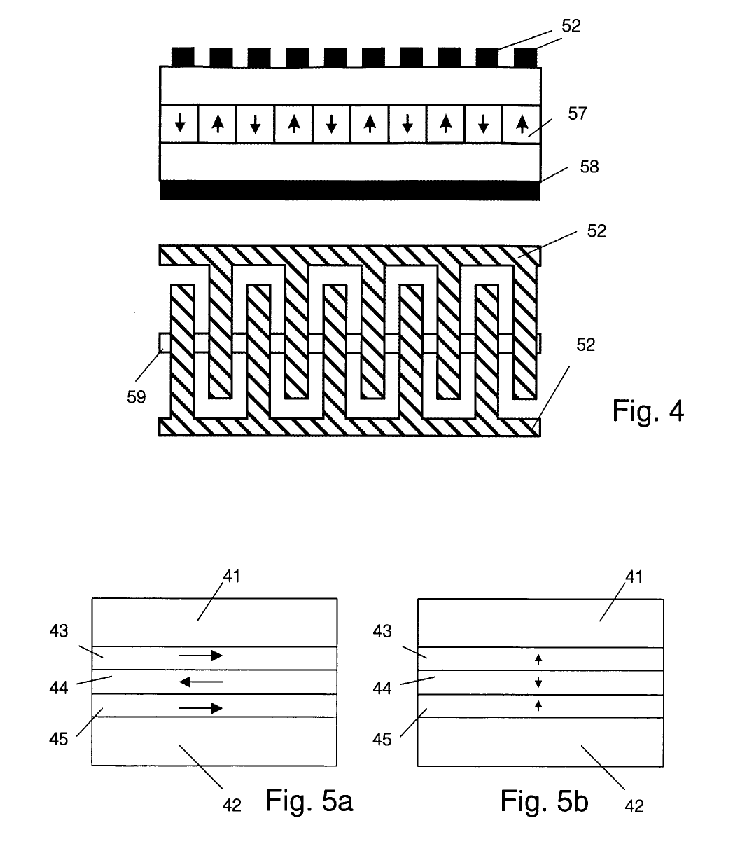

Two methods are introduced in the current disclosure to achieve phase matching in the described nonlinear waveguide, which can be fabricated by the method disclosed before. First one can use the “quasi phase matching method” in which in the fabricated nonlinear waveguide the direction of the spontaneous polarization is reversed in half-length of the coherent length which is the length in which the guided mode for idler, signal and frequency became out of phase. This technique is widely known as quasi-phase matching and has been applied to bulk crystals. Similar methods can be used for efficient second harmonic generation and parametric amplification for the described nonlinear waveguide. For this purpose the top electrode layer 52 is patterned periodically after the fabrication of the waveguide, which can be a ridge or channel waveguide as shown in FIG. 4. The period for the electrodes 52 depends on the desired wavelength and can be between 1 μm to several 10s of micrometers. As an example, for an amplifier at 1.55 μm band, one needs an electrode spacing of 2 μm. Next the nonlinear material is poled by applying a voltage to the electrodes. The poling is very simple in this case as compared to the bulk crystal case since one can apply fields higher than the coercive field of the nonlinear material and immediately switch the domains. In FIG. 4, the waveguide is indicated by reference numeral 59.

A second method which can be used for phase matching using the described nonlinear waveguide is the effective index phase matching. In this method, the effective index of the signal and idler guided modes are made equal to effective index of a higher order mode at pump frequency. Since the refractive index of the material increases with the frequency w it is only possible to match fundamental mode at idler and signal frequencies with higher order modes at pump frequency. However the overlap integral between modes with different orders is normally small or zero. The overlap integral for mode conversion is:

S=∫d(x,y)Eₘ^{(ω}^{ₚ}⁾(x,y)(Eₙ^{(ω}^{ₛ}⁾(x,y)Eₙ^{(ω}^{ᵢ}⁾(x,y))dxdy (3)

where E is the electric field for the guided mode and d is the nonlinear susceptibility and x and y are the Cartesian coordinates and m and n are mode orders. Since different guided modes are orthogonal, the overlap integral is small or zero. However if the sign of d in equation (3) is changed when the mode sign for the E^{(ωp)}, the more rapidly varying electric field, changes, the overlap integral will be large. An example of a core structure for a parametric amplifier is depicted in FIG. 5a and 5b. The structure comprises, between two layers 41, 42 of cladding material, for example SiO₂, three ferroelectric crystal layers 43, 44, 45 with different directions of their spontaneous polarization. The center layer 44 has a direction of spontaneous polarization that is opposed to the direction of the spontaneous polarization of the outer layers 43, 44. In FIG. 5a, the layers are polarized in-plane, whereas FIG. 5b shows an example of an out-of-plane polarization of the layers. Since the direction of spontaneous polarization (and hence d in Formula 3) changes, the overlap integral is maximized using this configuration. The structures of FIGS. 5a and 5b may be produced by repeating the method described above with crystals with different directions of their spontaneous polarization vector.

In the following, it is explained why this type of structure is very useful for nonlinear optical wave mixing. This is the case for the structure of FIGS. 5a and 5b.

Whereas the structures shown in FIGS. 5a and 5b and also in the figure described further below comprise three layers of opposing polarization, instead of three layers also two layers or more than three layers may be chosen. The important thing is that the sign of the susceptibility changes approximately when the sign of the E^{(ωp)} changes.

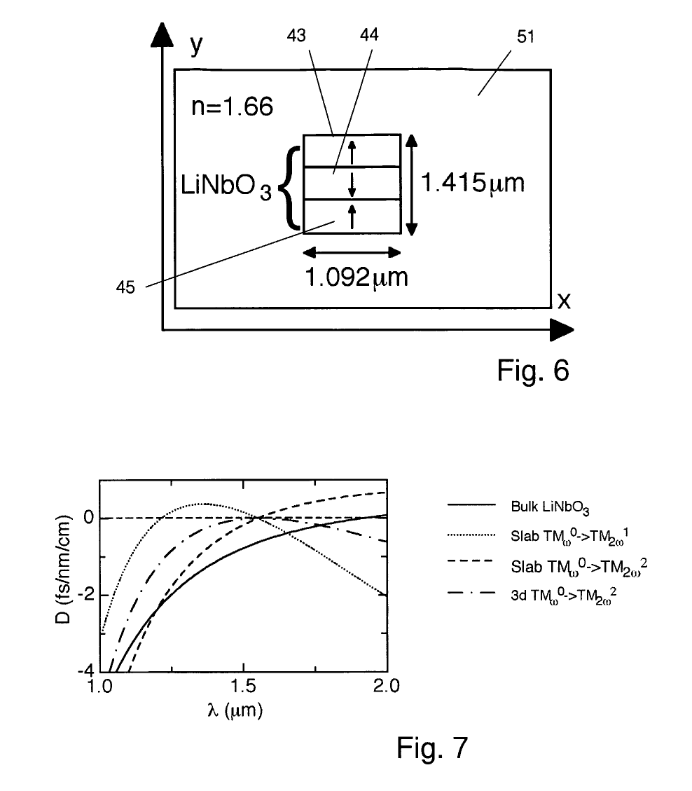

An example of an amplifier structure that is adjusted for a wavelength of 1.55 μm, a telecommunication wavelength, is shown in FIG. 6. In FIG. 6, the optically nonlinear layers 43, 44, 45 are laterally confined. The lateral confinement of the layers can be made based on a structure as in FIG. 5b (without topmost cladding layer 41) by standard photolithography and etching structuring techniques which are not a subject of the invention and will not be described in any detail here. The amplifier structure of FIG. 6 comprises a cladding 51 surrounding the three optically nonlinear layers. The cladding, the index of refraction may be adjusted as described in more detail below, may be for example a Silicon oxide fabricated by PE-CVD. The dimensions of the cladding in x and y direction, referring to the coordinate system drawn in the Figure, are not critical.

The structure in FIG. 6 comprising LiNbO₃ as optically nonlinear material and comprising the ferroelectric material dimensions shown in the Figure is designed as to maximize the overlap integral S for phase matching the fundamental TM mode at ωᵢ and ωₛ to the second mode of TM mode at ωₚ using e.g. d₃₃ of LiNbO₃ in a 3D waveguide at 1.55 μm. A “3D waveguide” in this context is a waveguide that is laterally confined in both directions, as opposed to a 2D waveguide or “slab” waveguide that is only confined vertically in one direction and is formed along a plane. d₃₃ denotes the y component of the susceptibility, y being normal to the propagation direction in the 3D waveguide The gain coefficient for parametric amplifier is given by:

$$G = \frac{1}{4} exp ( 2 \sqrt{η {P}_{pump}} L ) \qquad ( 4 )$$

where η is the second harmonic conversion efficiency (being related to the gain for parametric amplification), L is the length of the amplifier and Pₚᵤₘₚ is the pump power. The nonlinearity (conversion efficiency) for TM₀^{ω}→TM₂^{2ω} is as high as η=3000%/Wcm² for LiNbO₃ at 1.55 μm. Considering this calculated efficiency and assuming a pump power of Pₚᵤₘₚ=300 mW and L=1 cm, one can obtain G as high as 20 dB.

To achieve a good amplifier, it is necessary to achieve large bandwidth as well as high gain. In parametric amplification the required phase matching is written as:

n(ωₚ)ωₚ=n(ωₛ)ωₛ+n(ωᵢ)ωᵢ (5)

where p, s and i are pump, signal and idler frequency respectively. If the effective index is a linear function of the wavelength (i.e. if the dispersion of the waveguide is zero) the phase matching can be achieved over a large wavelength range.

The effective refractive index is a function of both the material dispersion and the waveguide dispersion. So in general the effective refractive index is a complicated function of the wavelength. One can approximate the effective index using the Taylor series expansion:

$$n ( λ ) = n ( {λ}_{0} ) + \frac{d n ( λ )}{d λ} ( λ - {λ}_{0} ) + \frac{{d}^{2} n ( λ )}{d {λ}^{2}} {( λ - {λ}_{0} )}^{2} + … \qquad ( 6 )$$

So if the second derivative of the effective refractive index with respect to wavelength is zero and higher order terms are negligible then the effective index is a linear function of the wavelength and the phase matching condition will be achieved over a large wavelength range. Notice that this is identical to the condition of making the chromatic dispersion equal to zero in an optical fiber for high-speed transmission of signals:

$$D ( λ ) = - \frac{λ}{c} \frac{{d}^{2} {n}_{e}}{d {λ}^{2}} = 0 \qquad ( 7 )$$

where D(λ) is the chromatic dispersion (CD). Normally in electro-optic crystals this condition is not satisfied for the material dispersion. FIG. 7 shows the CD as a function of the wavelength for an LiNbO₃ crystal (solid curve). As it can be seen this function is always negative in the visible and the infrared wavelengths of interest. It is therefore impossible to satisfy phase matching over a long wavelength range using bulk crystal. However if one calculates the CD of a waveguide mode one will get wavelength regions, where the CD is positive. Therefore these two effects can cancel each other and it is possible to achieve zero CD at a desired wavelength. This is again identical to shifting of the zero of chromatic dispersion by carefully designing the fiber. Notice that now we require two conditions to be satisfied at the same time. First, one needs to satisfy the phase matching condition at a given wavelength and second, one needs the CD to go to zero. This can be achieved by changing both the refractive index of the cladding and the core thickness. Thus, using the channel (3d) waveguide as described above it is possible to achieve zero dispersion as opposed to the bulk case, which is another advantage for the waveguides fabricated. This structure is made by using the method described above for the fabrication of thin films and by deposition of the glass material with adjusted refractive index using PECVD method for the cladding layers. Methods and computer programs for carrying out calculations of optical quantities such as the chromatic dispersion depending on dimensions, indexes of refraction etc. are known and are not described in any detail here. A commercially available computer program is for example a software named ‘Selene’ by the company C2V.

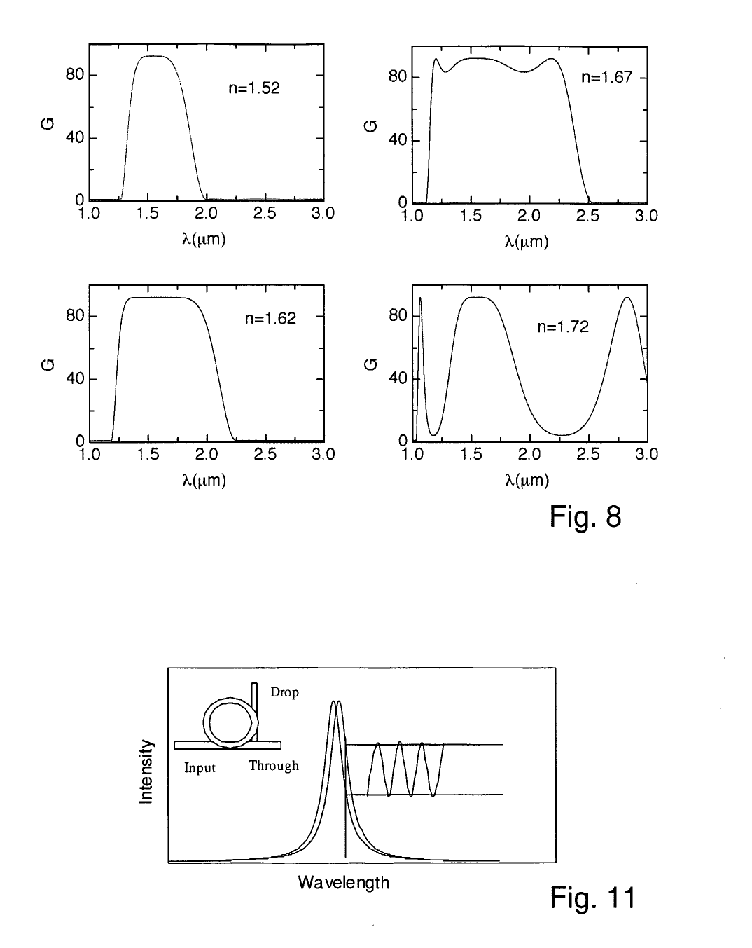

As an example consider the design of a parametric amplifier at 1.55 μm using LiNbO₃. To design the right structure the right thickness is obtained, which satisfies the phase matching condition for each cladding refractive index. Next, the dispersion is calculated. Table 1 summarizes the calculated waveguides thickness and cladding indices, which satisfy the phase matching condition and no dispersion for slab and 3d waveguides of LiNbO₃. The dispersion can be forced to become zero at the wavelength of 1.55 μm for both TE and TM modes of 3d waveguides (and, practically less importantly, for TM slab waveguide, too, whereas the dispersion cannot be forced to zero for the TE mode of a slab waveguide of LiNbO₃ for practical numbers for the refractive index of the cladding). FIG. 7 also shows the dispersion as a function of wavelength for the designs in Table 1 as a function of wavelength. Notice that for 3D waveguides, one has an extra degree of freedom for choosing the aspect ratio of the waveguide. This is used for polarization independent phase matching. The amplification gain spectrum for the slab waveguide is plotted in FIG. 8 for TM₀^{ω} [symbol] TM₂^{2ω}, corresponding to the dashed line in FIG. 7, conversion for different refractive indices n of the cladding. As it can be seen the gain spectrum is very wide (over 500 nm).

TABLE 1
The calculated thickness and refractive index of the cladding to
achieve phase matching and zero chromatic dispersion for
different conversion schemes:

| | Core | Cladding | Width | |
|---|---|---|---|---|
| | Thickness | refractive | (3d) | Dispersion |
| | (μm) | index | (μm) | (fs/nm/cm) |
| Slab | 0.728 | 1.48 | — | 0 |
| TM₀^{ω} [symbol] TM₁^{2ω} | | | | |
| Slab | 2.045 | 1.6 | — | 0.027 |
| TM₀^{ω} [symbol] TM₂^{2ω} | 2.044 | 1.62 | — | 0 |
| | 2.042 | 1.64 | — | −0.036 |
| | 2.041 | 1.66 | — | −0.07 |
| 3d TM | 1.577 | 1.75 | 1.492 | 0 |
| TM₀^{ω} [symbol] TM₂^{2ω} | 1.415 | 1.66 | 1.092 | 0 |
| 3d TE | 1.275 | 1.66 | 1.067 | 0 |
| TE₀^{ω} [symbol] TE₂^{2ω} | | | | |

A second issue is the coupling of the light into the structure. Notice that it is potentially difficult to excite a higher than fundamental mode of the waveguide. A better method is to generate the pump by second harmonic generation. Then, next to the signal, also a primary pump radiation of a frequency ωₚᵣ is coupled into the waveguide. The pump for the parametric amplification is the frequency doubled radiation with ωₚ=2ωₚᵣ. The signal may be in a frequency band below the primary radiation, in a frequency band above the primary radiation or in a combination thereof. According to an embodiment, the frequency of the primary radiation is chosen within or at the border of the frequency band of the signal. Then, if the phase matching condition is satisfied for the signal in the entire frequency band, it is also satisfied for the case in which ωₛ=ωᵢ(=ωₚᵣ). Therefore, the phase matching condition for frequency doubling is automatically satisfied. A numeric example: If the primary pump radiation has a frequency corresponding to a free space wavelength of λ=2πC/ωₚᵣ=1600 nm, the pump radiation has λ=800 nm, and the amplifier may amplify anything in the frequency range between 1600 nm and 1300 nm (assuming that the chromatic dispersion is zero in this range). This method has previously been demonstrated for periodically poled LiNbO₃ waveguides.

Notice that for this type of parametric amplifier one requires a large refractive index difference between core and cladding. Such a large difference has several advantages. First, the waveguides are small. This means that the intensity will be larger for a given power and hence the parametric gain will be high. Secondly, since the waveguides cores have a large refractive index difference compared with the cladding, one can make micron-sized bends. Spiral amplifiers, for example, can be realized for reduced size optical elements. Consider that the 1 cm length waveguide can be made into a spiral with 500 μm diameter for example. Thirdly, one can change the width of the waveguides or the period for the electrodes to achieve phase matching at different wavelengths. This means that in a single chip it is possible to extend the amplification wavelength. Fourthly, the noise figure of this type of amplifier is basically the quantum limited noise of 3 dB in phase-insensitive modes and, also, the noise figure can be made equal to zero in phase-sensitive modes.

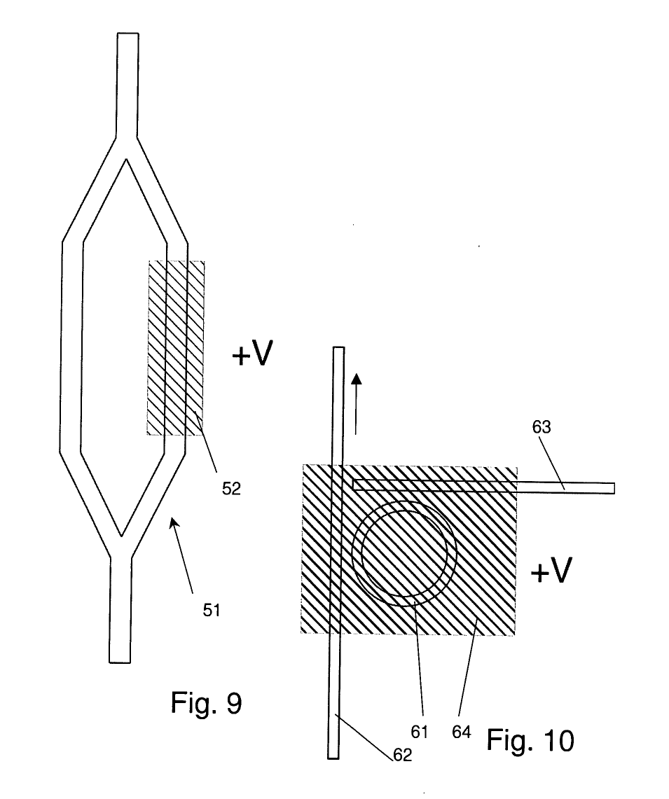

The thin films of nonlinear optical materials can also be used for the fabrication of optical switching devices and modulators. To achieve an optical switch, one needs to use a nonlinear optical material in an optical circuit. Since the refractive index of the fabricated thin film is very high compared to the cladding layer, one can make very small bends. So one can make optical devices with sizes as small as a few micrometers. The following devices can be made using the thin films of ferroelectric crystals for switching of light. The simplest device is a Mach-Zehnder modulator 51 as shown in FIG. 9. The modulator comprises two waveguide branches (or arms). In this device applying a voltage to the device on the electrode 52, influencing only one branch, changes the refractive index of said branch. The phase of transmitted light changes and due to interference the output light intensity will be modulated according to the applied voltage. By using a 3 dB coupler for coupling the incoming waveguides and the outgoing waveguides, one can achieve switching.

The next device, which can be made using the fabricated thin film, is an electro-optic micro-ring resonator as shown in FIG. 10. The light is coupled to the micro-resonator 61 from the input straight waveguide 62 and from the output straight waveguide 63. Due to the resonance, the light transmitted from the input waveguide to the output waveguide, as a function of the wavelength, shows a resonance peak at the resonance frequency of the ring resonator. The light transmitted to the output waveguide (or “drop channel” is plotted as a function of the wavelength in FIG. 11 (right curve). The remainder of the intensity is transmitted straight through the input waveguide (“through channel”). Using the fabricated thin films, as described before, the refractive index of the micro-resonator may be changed by applying a voltage to the electrode 64 of the device. This will shift the resonance wavelength as shown in FIG. 11 (left curve). Hence one can modulate or switch a wavelength close to the resonance wavelength as shown by the right inset in FIG. 11.

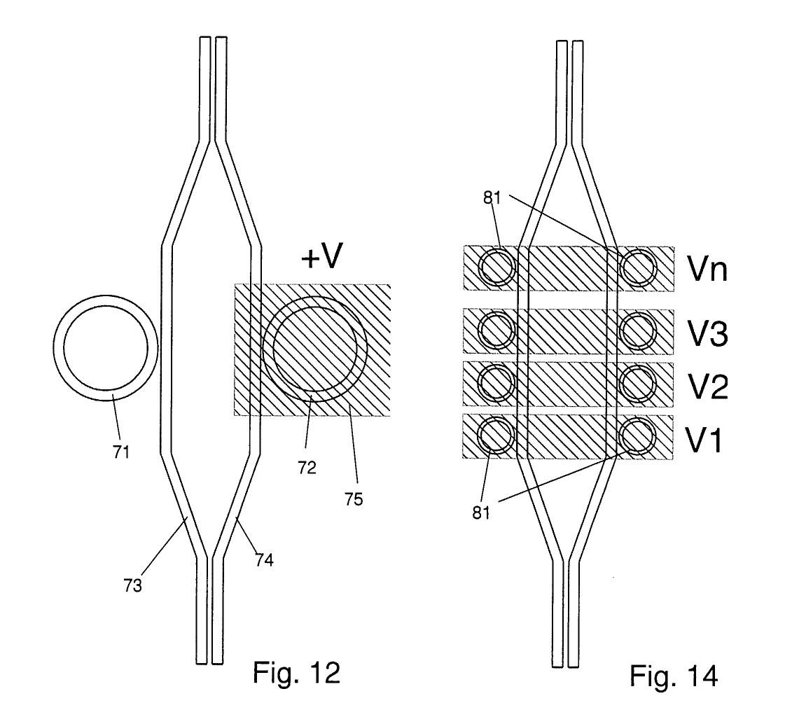

The next device is a wavelength selective switch in which two micro-resonators 71, 72 are coupled to two arms 73, 74 of a Mach-Zehnder modulator as shown in FIG. 12. On both, the input side and the output side, the arms 73, 74 are coupled by a 3 dB coupler. Notice that the phase of the light changes close to the resonance wavelength of a micro-resonator in a single micro-resonator coupled to a waveguide. Hence by making a structure, as shown in FIG. 12, comprising an electrode 75 and by poling the nonlinear core crystal of the micro-resonators in a push-pull fashion, and applying a voltage to the electrodes of the device one can modulate the transmitted light. The poling in a push-pull fashion may be realized by applying opposite voltage to the micro-resonator. The voltage must be such that the electric field is higher than the coercive field of the ferroelectric crystal, so that the spontaneous polarization or domains will switch to different directions for the two micro-resonators. As an alternative (with an electrode configuration different to the one shown in the drawing), the spontaneous polarization may be essentially identical in both micro-ring resonators, and the micro-ring resonators may comprise two electrodes and opposite voltage might be applied to them.

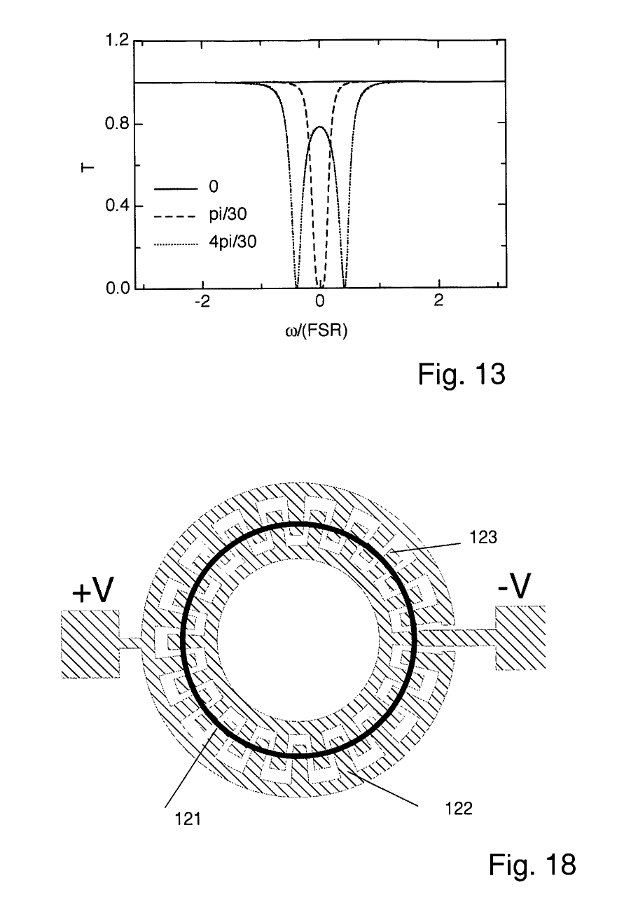

By shifting the resonance wavelength of the micro-resonators in different direction, the phase of the transmitted light will change and similar to a Mach-Zehnder device the light will be switched. Notice that this is very similar to a Mach-Zehnder modulator. However, this structure is wavelength sensitive. The light wavelength must be close to the resonance wavelength of the resonator to achieve modulation. The transmission for this modulator as a function of wavelength for different values of phase difference induced by electro-optic effect is shown in FIG. 13. There, the transmission through one branch is shown as a function of the difference between the frequency and the resonance frequency in units of the free spectral range (FSR). The solid curve shows the case where no voltage is applied and there is no phase difference between the branches. The dashed curve shows a case where the voltage is such that there is a phase difference between the branches of π/30, whereas the dotted curve corresponds to a phase difference of 4π/30.

Notice that in the micro-ring modulator the switching is achieved by shifting the resonance wavelength of the device. Hence, if one wavelength is switched on, the adjacent wavelength will switch off. However in the Mach-Zehnder based switches one can simply turn on a single wavelength or turn off the desired wavelength. This is very useful for the applications that will be discussed. Also, the Mach Zehnder based device is two times more sensitive to the applied voltage if it is made in a push-pull fashion. Finally, it is shown that any desired transfer function can be fabricated using two all pass filters in a Mach-Zehnder structure. Hence, one can make higher order switches simply by adding more resonators coupled to the waveguide.

Many applications can be considered for the wavelength selective switches introduced. One can consider, for example, a multi-wavelength modulator as shown in FIG. 14. This structure comprises a plurality of pairs of micro-rings 81 (in the Figure, only four pairs 1, 2, 3, and n are shown). Each pair of micro-rings has a different, given resonance wavelength and is adjusted close to resonance at that given wavelength. Hence, they will only modulate the desired wavelength and pass the rest unaffected. So it is possible to modulate different wavelengths in a small single chip. Using practical devices one can modulate up to 100 different wavelengths at a speed of 10 Gbit/sec. Hence it is possible to transfer about 1 Tbit of data in a single waveguide to the optical signal. This can be used for computer interconnect for example.

Also one can consider the structure as a wavelength selective switch in which the desired wavelengths will be switched to the desired output channel. One can switch different wavelengths in a single device as shown in FIG. 14. This can be used in wavelength routers as depicted in FIG. 15. FIG. 15 shows a section of a wavelength router which comprises a plurality of single devices of FIG. 14, connected to a switch network as schematically shown in FIG. 15. For reasons of clarity, the electrodes are not shown in FIG. 15. A wavelength router is a device in which optical signals of different wavelength can be routed, in a wavelength selective manner, from any input waveguide (in the figure for example at the bottom) to any output waveguide (in the figure on a level, or stage, above the shown topmost level). Using the optical circuit as shown in FIG. 15 one can achieve this function. Using the fabricated thin films it is possible to make this wavelength router. Notice that the number of switching stages must be equal to the number of input waveguide so that one can switch from any input waveguide to any output waveguide.

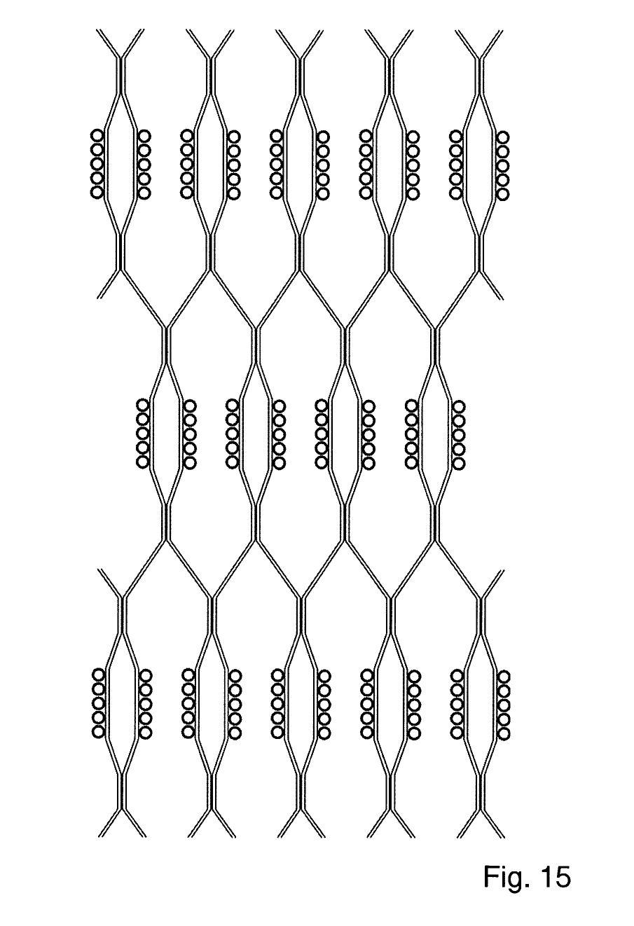

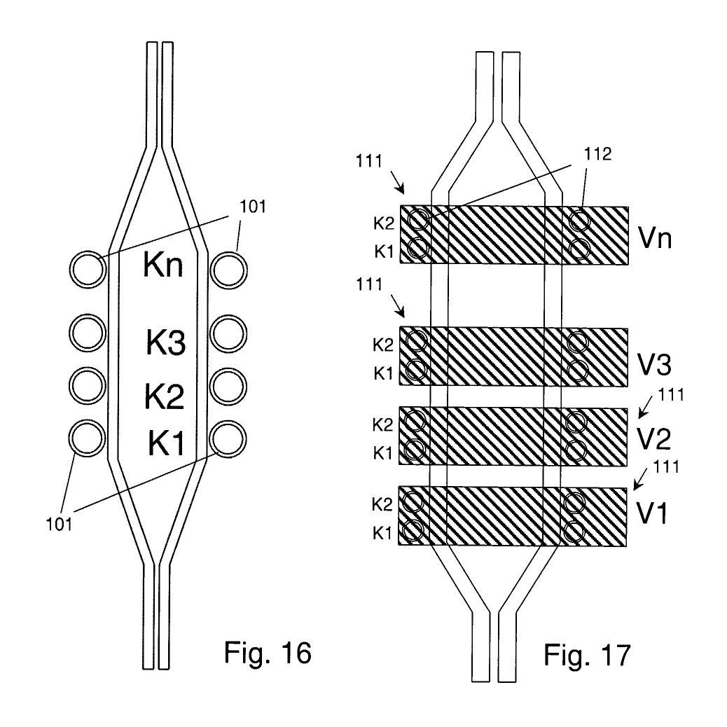

Notice that the micro-resonator, as described above, is a wavelength selective filter. Also more complicated filters with specific characteristics can be fabricated by coupling several micro-resonator pairs with different coupling constants and different phase differences to achieve different contributions to a tailored broadband filter. Such a broadband filter, for example corresponding to a square function filter, may ultimately help to achieve lower cross talk between adjacent channels when radiation of not only one frequency is to be switched. These filters can be in the form of the device shown in FIG. 16, where the K1, K2, K3, . . . Kn denote different coupling constants of the micro-resonator pairs 101. Notice that any desirable transfer function can be realized by the sum or difference of two all-pass filters. Using the device shown in FIG. 16 and by carefully adjusting the coupling coefficient one can achieve a desirable transfer function for filtering applications.

This principle may be combined with the principle explained referring to FIG. 14. The phase changes brought about by the micro-resonator pairs may be switched on and off if they are caused by changes of refractive index in one (or both) micro-resonators of a pair due to a voltage applied to an electrode. A switch may comprise several groups of resonator pairs with different coupling constants and for different phase changes as shown in FIG. 17. There, every group 111 of resonator pairs, constituting a switchable filter for a given frequency band, for reasons of simplicity only comprises two pairs 112 characterized by coupling constants K1, K2. In reality, groups of more filter pairs, with arbitrary filter constants, may be chosen. In the shown embodiment, each group of filter pairs comprises one common electrode for applying a voltage V1, V2, . . . Vn; however, electrodes for each filter pair may be provided individually.

Multi-frequency switches as shown in FIG. 17 may be combined to routing networks as in FIG. 15.

Finally one can change the refractive index of the waveguide periodically and couple the light out of the waveguide made by the above described method. FIG. 18 shows the device concept. An electro-optic micro-resonator 121 is considered. A periodic field is created by applying a voltage to the electrodes 122, 123 of this device. The electrodes are arranged in a manner that the positive and the negative electrode on the ring resonator alternate in a regular sequence, for example by being formed as shown in FIG. 18. The periodic field, thus resulting, induces a periodic index change in the core of the micro-resonator. This index change will couple the light out of the micro-resonator. This is similar to a grating coupler for a straight wave-guide. Notice that this grating is induced through an electro-optic effect. Hence one can induce the grating very rapidly. So it is possible to make an electro-optic loss induced switch. One can use this effect to change the losses for micro-resonators. Also the introduction of losses is important for coupled cavity resonators. To achieve a precise transfer function for coupled cavity resonators one needs to achieve a precise resonance wavelength and precise coupling. The resonance wavelength can be easily tuned using the electro-optic effect. However the coupling cannot be adjusted after the device is fabricated. However by introduction of losses into the cavity one can compensate for the inaccuracy in the coupling coefficients. By the method introduced in this invention one can tune both losses and resonance wavelength using electro-optic effect. This is very useful to achieve coupled cavity devices.

Using a perturbative method, one can calculate the coupling between the guided modes and radiation modes in micro-ring resonators. Assuming that the perturbation due to index change is given by:

δn_{∞}(r,φ)=δnexp(imφ) (8)

where n_{co} is the core index, m is the number of periods of electrodes and δn is the electro-optic index change. Also, assuming the electric filed for guided mode is given by:

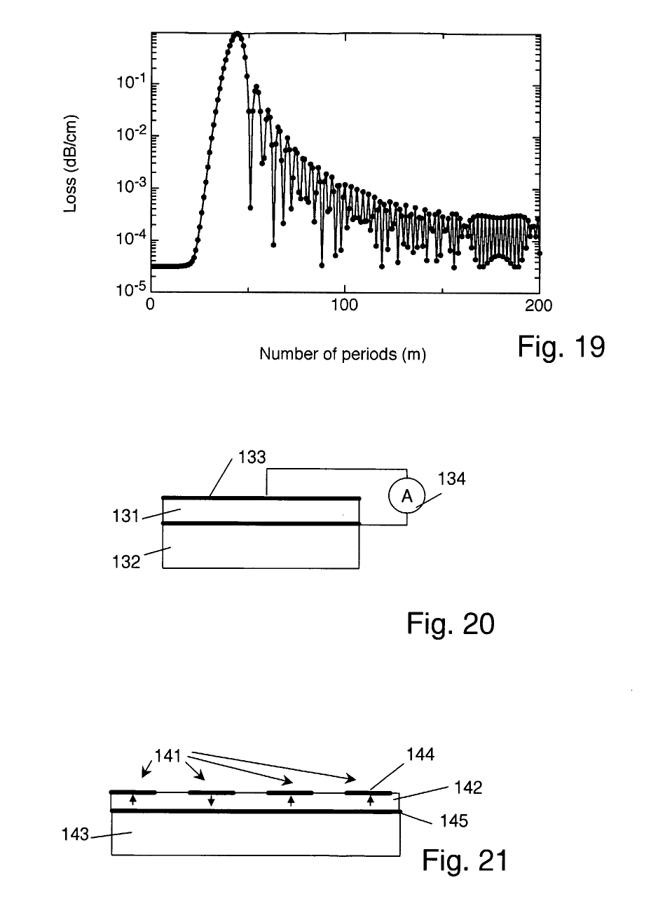

E_{z}(r,φ)=Φ(r)e^{iβ}^{_{φ}} (9)

Where Φ (r) is the filed profile and P is an integer number for resonance modes, one can show that the radiated power is given by:

$${P}_{rad} = \frac{1}{8} \sqrt{\frac{{ɛ}_{0}}{{μ}_{0}}} {{k}_{0}^{3} ( 2 π )}^{2} {( {\int }_{0}^{R} {J}_{β - m} ( - {n}_{cl} {k}_{0} {r}^{′} ) ( 2 {n}_{∞} δ n ) Φ ( {r}^{′} ) d {r}^{′} )}^{2} \qquad ( 10 )$$

Where J is the Bessel function and no, is the cladding refractive index. FIG. 19 shows the calculated radiated power for a micro-resonator as a function of the number of periods for the electrodes m. The micro-resonator is assumed to have an outer diameter of 29 μm, core index of 1.6, cladding index of 1.3 and the optical wavelength is equal to 1.55 μm. The electro-optic coefficient is assumed to be 30 pm/V. As can be seen from FIG. 19, when m is very small the losses are limited by leakage losses. By increasing m further, the losses rapidly increase since the guided mode matches to the first radiation mode. By increasing m further the losses decrease since the overlap integral between the guided modes and radiation modes decreases. It is interesting to note that by applying 10V/μm it is possible to induce 2 dB/cm loss. Notice that the losses increase as a square function of the index change. So by applying 20V/μm the losses are as high as 4 dB/cm. This value is very high and can be used in a practical electro-optic micro-resonator to make switches or to compensate for the in accuracy in the coupling in multi-cavity micro-ring resonators.

Notice that all the required functions in a multi-wavelength communication system are realized with this single technology. The generation (laser), amplification, switching and modulation and filtering can be all realized using the described thin films. Also polarization sensitive devices can be made using the ferroelectric crystal waveguide described as well as by choosing the right configuration. A skilled person can realize these configurations.

Further, also piezoelectric devices and pyroelectric devices or ferroelectric memory elements may be fabricated using this technique.

An example of a pyroelectric sensor element is schematically drawing in FIG. 20. The sensor comprises a ferroelectric layer 31 produced according to the above-described method placed on a substrate 32. A change of temperature causes a change of the polarization of the ferroelectric layer and thus induces a small current to or from an electrode 133 placed nearby. The current measurement 134 means are also represented in the figure.

In the device of FIG. 20, as well as in the one of FIG. 21 described below, a dielectric buffer layer between the electrode and the ferroelectric layer that may be present for production by the above mentioned method is omitted, since it does not have a function and may therefore be chosen to be very thin, for example considerably thinner than the ferroelectric layer.

The method according to the invention may also be used for producing ferroelectric memory elements. By the method according to the invention, small-sized, stable ferroelectric memory elements become feasible. FIG. 21, schematically, depicts a ferroelectric memory device comprising four memory elements each representing one information bit. The device comprises a layer 142 fabricated by the method according to the invention on a substrate and a plurality of electrodes 141 with which the information bits can be written (by applying either a negative or positive voltage) or read out. A skilled person can realize electronic circuits for this purpose.

Various other embodiments may be envisaged without departing from the scope and spirit of the invention.

1. A method of producing a device with a ferroelectric thin film on a first substrate, the method comprising the steps of:
providing a ferroelectric crystal,
irradiating a first surface of said ferroelectric crystal with ions so that a damaged layer is created underneath said first surface,
bonding a block of material including said first substrate to said ferroelectric crystal to create a bonded element, wherein an interface is formed between said first surface and a second surface of said block, and
heating the bonded element and separating it at the damaged layer, so that a ferroelectric crystal layer remains supported by the first substrate.

2. A method according to claim 1, further comprising the steps of:
prior to bonding the block to thea second substrate, fabricating said block by providing the first substrate, and
applying a layer of electrically conducting material to the first substrate.

3. A method according to claim 2, wherein the fabricating of said block further comprises the step of applying a dielectric layer to said layer of electrically conducting material, said dielectric layer forming said second surface.

4. A method according to claim 1, wherein the ferroelectric crystal is a LiNbO₃ crystal.

5. A method according to claim 1, wherein said block comprises a second ferroelectric crystal, said second ferroelectric crystal preferably being a LiNbO₃ crystal.

6. A method according to claim 1, wherein material at said second surface has an index of refraction that is lower than the index of refraction of said ferroelectric crystal by at least 10%, and wherein said material is preferably a silicon oxide.

7. A method according to claim 1, further comprising the step of laterally structuring the ferroelectric crystal layer so that a waveguide core of a 3d waveguide is formed.

8. A method according to claim 1, further comprising the step of chemical mechanical polishing of the first substrate prior to the bonding.

9. A method according to claim 1 comprising the step of annealing and/or polishing the ferroelectric crystal layer after the separating step.

10. A method according to claim 1, wherein the ferroelectric crystal is a bulk ferroelectric crystal.

11. An optical or optoelectronic or electromechanical or piezoelectric or pyroelectric or memory device comprising:
a first substrate and ferroelectric crystal material supported by said substrate, wherein said ferroelectric crystal material has been transferred as a ferroelectric layer from a ferroelectric crystal using the method according to claim 1.

12. A device according to claim 11, further comprising an electrode being formed in a layer parallel to the ferroelectric crystal layer and being positioned between the first substrate and the ferroelectric crystal layer.

13. A device according to claim 12, wherein said electrode is arranged between said first substrate and a dielectric layer on which the ferroelectric crystal layer is arranged.

14. A device according to claim 11, being an optical wavelength selective filter comprising two waveguide branches, each branch being coupled to at least one micro-resonator, wherein waveguide cores of the waveguide branches and the micro-resonators comprise said ferroelectric material.

15. A device according to claim 12, being a Mach-Zehnder modulator comprising two waveguide branches, cores of which are comprise said ferroelectric material, and wherein at least one branch comprises an electrode for influencing the index of refraction of the ferroelectric material.

16. A device according to claim 12, being a wavelength selective switch with two waveguide branches, each branch being coupled to at least one micro-resonator, wherein waveguide cores of the waveguide branches and the micro-resonators comprise said ferroelectric material, and wherein at least one branch and/or a micro-resonator coupled to said wavelength selective switch comprises an electrode for influencing the index of refraction of the ferroelectric material.

17. A device according to claim 16, comprising a plurality of micro-resonator pairs or groups of micro-resonator pairs, each micro-resonator pair comprising a micro-resonator coupled to one waveguide branch and one micro-resonator coupled to the other waveguide branch, each micro-resonator pair or group of micro-resonator pairs comprising an electrode for influencing the index of refraction of the ferroelectric material, the different electrodes being separated from each other.

18. A dynamic wavelength router for routing optical signals of different wavelengths comprising a plurality of devices according to claim 17 connected to each other network-like.

19. A device according to claim 12, being a switchable out-coupler comprising an electrode for applying a periodic field to the ferroelectric material.

20. A device according to claim 12, being a pyroelectric sensor or a piezoelectric device.

21. A device according to claim 12, being a ferroelectric memory device.

22. An parametric amplifier or frequency doubling device, fabricated using a method according to claim 1, comprising a waveguide formed by a layered structure and a cladding, wherein the layered structure comprises at least two layers of a ferroelectric material arranged adjacent to each other in a layer sequence, wherein the spontaneous polarization of neighboring layers of the layer sequence differs.

23. A parametric amplifier or frequency doubling device according to claim 22, wherein the layered structure comprises exactly three layers of one ferroelectric material.

24. A parametric amplifier or frequency doubling device according to claim 22, wherein the spontaneous polarization of neighboring layers in the layer sequence is opposed.

25. A parametric amplifier or frequency doubling device according to claim 22, wherein the thickness of one layer of the layered structure is correlated to the waveguide configuration in a manner such that a higher than fundamental mode has a node close to an interface between two adjacent layers.

26. A parametric amplifier or frequency doubling device according to claim 22, wherein the dimensions of the waveguide are chosen such that the waveguide contribution to a chromatic dispersion and a chromatic dispersion contributed by the ferroelectric material compensate each other in a certain wavelength range.

27. A parametric amplifier, fabricated using a method according to claim 1, comprising a waveguide formed by a layered structure and a cladding and further comprising electrodes with a periodic pattern, so a core waveguide may be poled periodically to achieve quasi phase matching for frequency doubling or parametric amplification.
